(19) United States
(12) Patent Application Publication
(10) Pub. No.: US 2015/0028357 A1
(43) Pub. Date: Jan. 29, 2015

(54) PACKAGE STRUCTURE OF AN OPTICAL MODULE

(71) Applicant: Lingsen Precision Industries, Ltd, Taichung City (TW)

(72) Inventors: Ming-Te TU, Taichung City (TW); Yao-Ting YEH, Taichung City (TW)

(73) Assignee: Lingsen Precision Industries, Ltd, Taichung City (TW)

(21) Appl. No.: 14/072,154

(22) Filed: Nov. 5, 2013

(30) Foreign Application Priority Data
Jul. 25, 2013 (TW) 102126697

(51) Int. Cl. H01L 25/16; H01L 25/00

(52) U.S. Cl. CPC H01L 25/167; H01L 25/50
USPC 257/82; 438/25

(57) ABSTRACT

This invention relates to a package structure of an optical module. A light emitting and light receiving chips are disposed on a light emitting and light receiving region of the substrate, respectively. Two encapsulating gels cover the light emitting chip and the light receiving chip, respectively, and form a first and a second hemispherical lens portions on the light emitting chip and the light receiving chip, respectively. A cover is affixed on the substrate and each of the encapsulating gels and has a light emitting hole and a light receiving hole, wherein the first and the second lens portions are accommodated, respectively. An engaging means is formed on an adjacent surface between each encapsulating gels and the cover in a horizontal direction. Thereby, the package structure of the optical module of the present invention increases the connection region between each encapsulating gels and the cover to enhance the engagement.

### BACKGROUND OF THE INVENTION

1. Field of the Invention

The present invention relates to a package structure, especially related to a package structure of an optical module.

2. Descriptions of the Related Art

Currently, optical proximity sensing modules have become a mainstream technology choice of the new generation of intelligent electronic devices (such as smart phones). When the electronic device is close to someone's ears (face detection) or placed in a pocket, the module will immediately turn off the screen display to save power and prevent accidental screen presses to provide a better user experience. The action principle of the module is emitting a light source with a light emitting chip, such as a light emitting diode (LED), the light is reflected by the surface of an object and is then projected onto a light receiving chip to be converted to electrical signals for subsequent processing. After the aforementioned conventional optical sensing module is packaged, the power of the light emitted by the light emitting chip of the module reflected by the surface of the object has been greatly reduced so that the light signal received by the adjacent light receiving chip is bad or even cannot be received. This causes the signal of the recited intelligent electronic devices can not be stable and accurate for interpretation.

Taiwan Patent M399313 provides a proximity sensing package structure to improve this defect. The package structure includes a base, a barrier wall vertically connected to the periphery of the base, and a cover plate covering the barrier wall to form a receiving space. A partition board is disposed in the receiving space to segment this receiving space. Thereby, the light emitting chip and the light receiving chip can be spaced and arranged on the substrate to avoid interference of a light source and reduce product performance.

However, the cover plate of the above patent is adhered to the barrier wall, and the connection region is at the periphery of the barrier wall. When a lateral force is applied, the cover is easily dislocated because the small connection region with the barrier wall and is even detached from the barrier wall.

### SUMMARY OF THE INVENTION

The main objective of the present invention is to provide a package structure of an optical module to effectively improve the luminous efficiency of the light emitting chip and to improve the defect of the reception of the light receiving chip.

The secondary objective of the invention is to provide a package structure of an optical module to effectively increase the connection region of package structure to enhance the engagement.

In order to achieve the above objectives, the package structure of an optical module of the present invention comprises a substrate, a light emitting chip, a light receiving chip, two encapsulating gels, a cover and an engaging means. The substrate defines a light emitting region and a light receiving region. The light emitting chip and the light receiving chip are disposed on the light emitting region and the light receiving region of the substrate, respectively. Each of the encapsulating gels coat on the light emitting chip and the light receiving chip, respectively, and each of the encapsulating gels form a first lens portion and a second lens portion, each of which is a hemispherical shape, on the light emitting chip and the light receiving chip, respectively. The cover is disposed on the substrate and each of the encapsulating gels, along with having a light emitting hole and a light receiving hole, the light emitting hole and the light receiving hole being located on the light emitting chip and the light receiving chip, respectively, and the first lens portion and the second lens portion being accommodated in the light emitting hole and the light receiving hole. The engaging means is disposed on an adjacent surface between each of the encapsulating gels and the cover in a horizontal direction.

The engagement means comprises at least one concave on a horizontal surface of each of the encapsulating gels and a convex corresponding to a position of the concave on the cover, and the convex is inserted into the concave.

Each of the encapsulating gels and the cover are formed by molding.

A curvature of each of the first lens portion and the second lens portion of each of the encapsulating gels are the same or different.

Each of the encapsulating gels is made of translucent resin.

The cover is one piece and the material of the cover is opaque resin.

The substrate is a non-ceramic substrate, which comprises an organic Bismaleimide Triazine substrate.

A packaging method of an optical module, the method comprising the following steps of:

(a) defining a light emitting region and a light receiving region on a substrate;

(b) electrically connecting a light emitting chip and a light receiving chip to the substrate;

(c) forming a translucent encapsulating gels on the light emitting chip and the light receiver chip; and

(d) affixing an opaque cover on the substrate and encapsulating gels.

The step of electrically connecting is a wire bonding method process and a die attaching process.

The packaging method further comprises a step (e) of cutting or punching the optical module Made in the step (a) to step (d).

The package structure of the optical module of the present invention provides the encapsulating gels with different curvatures according to different needs to effectively improve the luminous efficiency of the light emitting chip and improve reception quality of the light receiving chip. Through the engaging means, the connection region between the encapsulating gels and the cover is increased to enhance the engagement of the package structure.

To provide a further understanding of the composition, characteristics and purpose of the present invention, the following are descriptions describe several embodiments of the present invention to explain the drawings in detail for people skilled in this technical field can implement. The following description lists the embodiments to illustrate the technical contents and characteristics of the present invention. People have a general knowledge of this technical field of the present invention can proceed with various simple modifications, replacements, or member omitting belonging to the scope of the present invention intended to protect.

### BRIEF DESCRIPTION OF THE DRAWINGS

FIG. 1 is a top view of a preferred embodiment of the present invention;

FIG. 2 is a cross-sectional view along the 2-2 section line of FIG. 1 of a preferred embodiment of the present invention;

FIG. 3 is an enlarged view of FIG. 2 to show the engaging means between each of the encapsulating gels and the cover; and

FIG. 4 is a packaging flow diagram of a preferred embodiment of the present invention.

### DESCRIPTION OF THE PREFERRED EMBODIMENT

In order to illustrate the structure, characteristics and effectiveness of the present invention in detail, a preferred embodiment and corresponding diagrams are illustrated as follows.

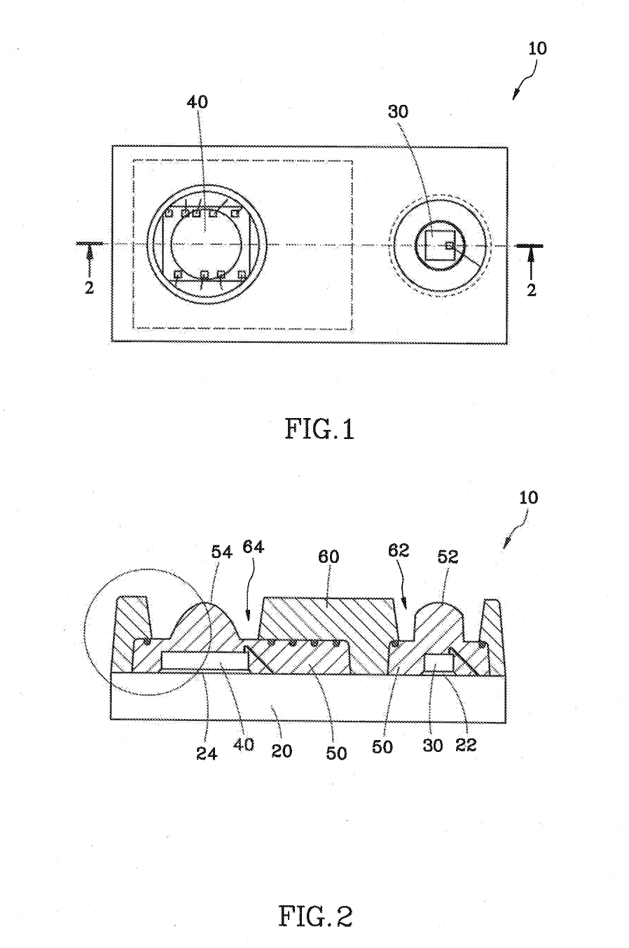

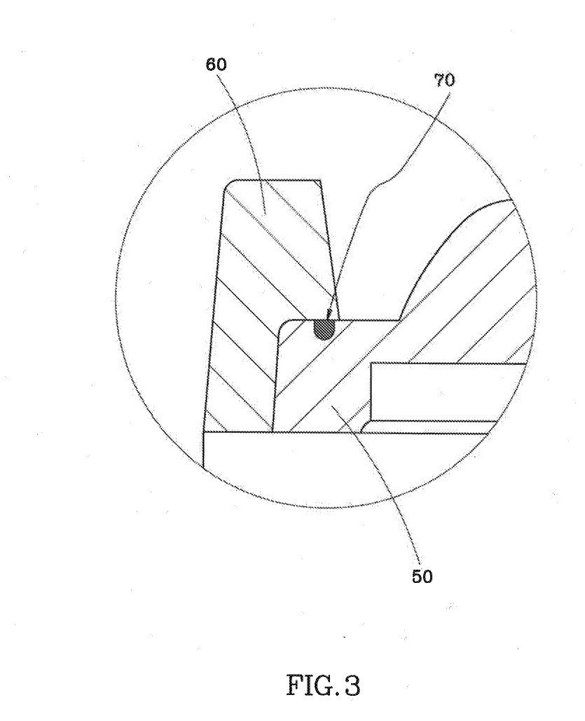

Please refer to FIG. 1 to FIG. 3, the package structure 10 of an optical module of a preferred embodiment of the present invention is a module cut from a general package array and comprises a substrate 20, a light emitting chip 30, a light receiving chip 40, two encapsulating gels 50, a cover 60, and an engaging means 70.

The substrate 20 in the preferred embodiment is a non-ceramic substrate, such as a Bismaleimide Triazine (known as BT) substrate or a glass fiber (known as FR4) substrate made of organic materials. Thereby, the material cost of the substrate 20 is low. The surface of the substrate 20 defines a light emitting region 22 and a light receiving region 24.

The light emitting chip 30 and the light receiving chip 40 are treated by a die attaching process and a wire bonding process and are disposed on the light emitting region 22 and the light receiving region 24 of the substrate 20. The light emitting chip 30 is used to emit light, and the light receiving chip 40 is used to receive the light emitted from the light emitting chip 30.

The material of each of the encapsulating gels 50 is translucent resin, take transparent epoxy resin as an example, each of the encapsulating gels 50 coats on the light emitting chip 30 and the light receiving chip 40 by first molding. Each of the encapsulating gels 50 forms a first lens portion 52 and the second lens portion 54, each of which is a hemispherical shape, on the light emitting chip 30 and the light receiving chip 40.

The cover 60 is integrally molded with opaque resin material, such as opaque epoxy resin. The cover 60 is affixed on the substrate 20 and each of the encapsulating gels 50 by a second molding. The cover 60 has a light emitting hole 62 and a light receiving hole 64 located above the light emitting chip 30 and the light receiving chip 40, respectively. Each of the first lens portion 52 and the second lens portion 54 of each of the encapsulating gels 50 is accommodated in the light emitting hole 30 and the light receiving hole 40, respectively. In the preferred embodiment of the present invention, the curvatures of the first and second lens portions 52, 54 can be the same or different to meet the different usage demands. When the curvature of the first lens portion 52 is larger, the light emitted from the emitting chip 30 covers a larger region. When the curvature of the second lens 54 is smaller, the second lens 54 is more effective to focus the reflected light. Thereby, the optical module of the present invention can effectively improve the luminous efficiency of the light emitting chip 30 and improve the bad reception of the light receiving chip 40.

The engaging means 70 is provided on the adjacent surface in the horizontal direction between each of the encapsulating gels 50 and the cover 60. The horizontal surface of each of the encapsulating gels 50 comprises at least one concave 56, and a convex 66 is formed corresponding to a position of the concave 56 on the cover 60. The convex 66 is inserted into the concave 56 to increase the connection region between each of the encapsulating gels 50 and the cover 60 to enhance the engagement.

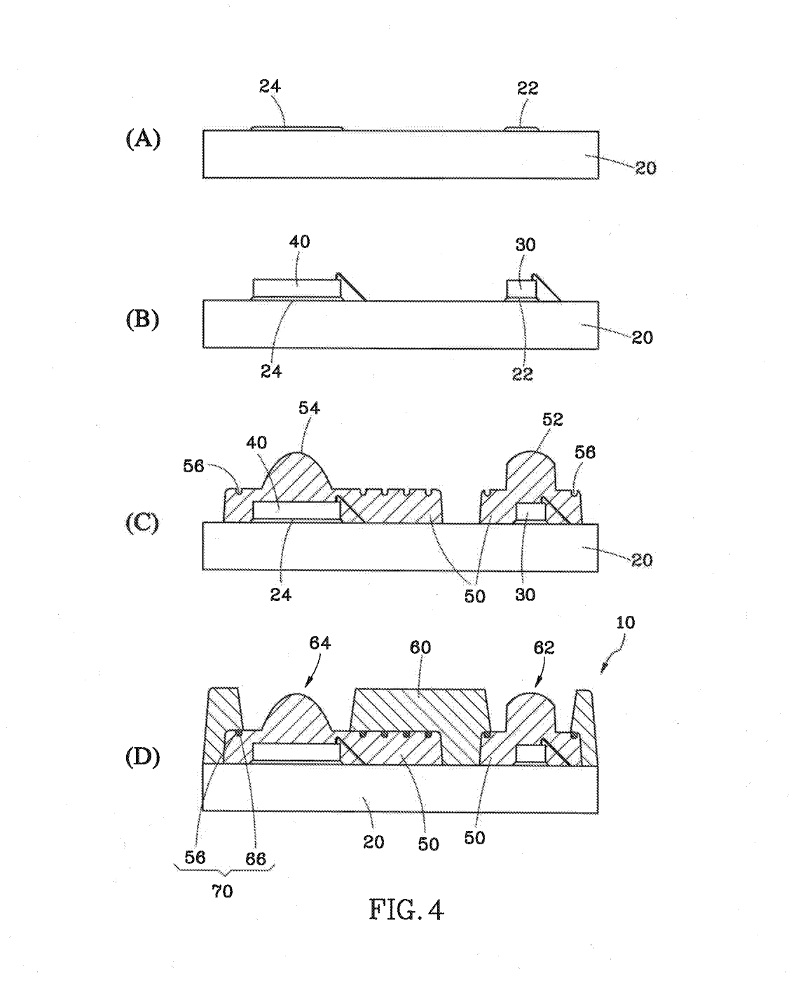

Referring to FIG. 4(A) to (D), the packaging flow of the optical module of the present invention is shown. The first step A is defining the light emitting region 22 and the light receiving region 24 on a single substrate 20 of each substrate array. The second step B is disposing the light emitting chip 30 and the light receiving chip 40 on the light emitting region 22 and the light receiving region 24 of the substrate 20 by the die attaching process and a wire bonding process. The third step C is molding each of the transparent encapsulating gels 50 on the light emitting chip 30 and the light receiving chip 40, respectively, to form the first lens portion 52 and the second lens portion 54, each of which is a hemispherical shape, and forming at least one concave 56 on the horizontal surface of each of the encapsulating gels 50. The fourth step D is molding the opaque cover 60 to be fixed on the substrate 20 and each of the encapsulating gels 50, and the cover has the light emitting hole 62, the light receiving hole 64 and the convex 66. The light emitting hole 62 and the light receiving hole 64 are located on the light emitting chip 30 and the light receiving chip 40. The first lens portion 52 and the second lens portion 54 of each of the encapsulating gels 50 is respectively accommodated in the light emitting hole 62 and the light receiving hole 64, and the convex 66 is corresponding to the position of the convex 56 to match with each other.

According to the preferred embodiment of the invention, the second step B to the fourth step D is to position the hemispherical mold of the first lens portion 52 and the second lens portion 54 to a predetermined position aligning the light emitting chip 30 and the light receiving chip 40 on the surface of the substrate 20. Then, the transparent resin is filled in the mold to cover each of the chip 30, 40. Since there's a male mold structure of the recessed hole 56 of the encapsulating gels 50 in the mold, the transparent resin forms the encapsulating gels 50, which is a hemispherical structure having a recess 56 on the horizontal surface with the structures encapsulating gels 50 after being shaped and retreated from the mold. Then a mold with the structure of the cover 60 is placed on the substrate 20, and the opaque resin fill into the mold until the opaque resin fills the mold or to a predetermined amount. After the opaque resin is shaped and retreated from the mold, the one piece cover 60 is provided. The cover 60 has the first lens portion 52 and second lens portion 54 corresponding to the light emitting hole 62 and the light receiving hole 64 and the convex 66 for the concave 56 to be matched. Thereby, the connection region between each of the encapsulating gels 50 and the cover 60 is increased for enhancing the engagement.

In summary, the light emitted from the light emitting chip 30 of the optical module of the present invention passes through the first lens portion 52 of the encapsulating gels 50 and then passes through the light emitting hole 62 of the cover 60 to be projected to the surface of the object. The light reflected from the surface of the object is received by the light receiving hole 64 of the cover 60 and is projected to the second lens portion 54 of the encapsulating gels 50. The light is focused and emitted to the light receiving chip 40, and the light receiving chip 40 converts the received light signals into electrical signals for operation processing. When emitting and receiving the light, the first lens portion 52 of the encapsulating gels 50 improves the luminous power of the light emitting chip 30, and the second lens portion 54 of the encapsulating gels 50 enhances the reception power of the tight receiving chip 40. Thereby, the light projected on the uneven surface of the object by the light emitting chip 30 can be reliably and stably received by the light receiving chip 40 after being reflected. The engaging means 70 effectively increases the connection region between each of the encapsulating gels 50 and the cover 60 to enhance the engagement.

The constituent elements in the above embodiments of the present invention are only for illustration and are not intended to limit the scope of the present invention. Other substitutions, equivalent elements or changes should be covered by the scope of the claim of the present invention.

What is claimed is:

1. A package structure of an optical module, comprising:
a substrate defining a light emitting region and a light receiving region;
a light emitting chip disposed on the light emitting region of the substrate;
a light receiving chip disposed on the light receiving region of the substrate;
two encapsulating gels coated on the light emitting chip and the light receiving chip, respectively, each of the encapsulating gels forming a first lens portion and a second lens portion, each of which is a hemispherical shape, on the light emitting chip and the light receiving chip, respectively;
a cover disposed on the substrate and each of the encapsulating gels, the cover having a light emitting hole and a light receiving hole, the light emitting hole and the light receiving hole being located on the light emitting chip and the light receiving chip, respectively, and the first lens portion and the second lens portion being accommodated in the light emitting hole and the light receiving hole; and
an engaging means disposed on an adjacent surface between each of the encapsulating gels and the cover in a horizontal direction.

2. The package structure of the optical module as claimed in claim 1, wherein the engagement means comprises at least one concave on a horizontal surface of each of the encapsulating gels and a convex corresponding to a position of the concave on the cover, and the convex is inserted into the concave.

3. The package structure of the optical module as claimed in claim 1, wherein each of the encapsulating gels and the cover are formed by molding.

4. The package structure of the optical module as claimed in claim 1, wherein a curvature of each of the first lens portion and the second lens of each of the encapsulating gels are the same or different.

5. The package structure of the optical module as claimed in claim 1, wherein each of the encapsulating gels is made of translucent resin.

6. The package structure of the optical module as claimed in claim 1, wherein the cover is one piece and the material of the cover is opaque resin.

7. The package structure of the optical module as claimed in claim 1, wherein the substrate is a non-ceramic substrate, which comprises an organic Bismaleimide Triazine substrate.

8. A packaging method of an optical module, the method comprising the following steps of:
(a) defining a light emitting region and a light receiving region on a substrate;
(b) electrically connecting a light emitting chip and a light receiving chip to the substrate;
(c) forming a translucent encapsulating gels on the light emitting chip and the light receiver chip; and
(d) affixing an opaque cover on the substrate and the encapsulating gels.

9. The packaging method of the optical module as claimed in claim 8, wherein the step of electrically connecting is a wire bonding method process and a die attaching process.

10. The packaging method of the optical module as claimed in claim 8, further comprising a step (e) of cutting or punching the optical module made in the step (a) to step (d).
